(19) United States
(12) Patent Application Publication
(10) Pub. No.: US 2004/0177199 A1
(43) Pub. Date: Sep. 9, 2004

(54) Method of arranging interface card in TV/Computer monitor expansion box

(76) Inventor: Jan-Sen Yang, Taipei (TW)

Correspondence Address: I-Ming Lin, 5672 Silver Valley Ave, Agoura Hills, CA, 91301, US

(21) Appl. No.: 10/383,343

(22) Filed: Mar. 7, 2003

(51) Int. Cl. H05K 7/10

(52) U.S. Cl. 710/301; 710/302

(57) ABSTRACT

A method of arranging an interface card in a TV/Computer monitor expansion box, including the step of installing a TV/Computer monitor expansion box in a TV/Computer monitor and the step of inserting an interface card into the TV/Computer monitor expansion box, permitting the inserted interface card to be electrically connected to the microprocessor of the TV/Computer monitor. In this way, the microprocessor of the TV/Computer monitor is controlled to operate subjectively to the function of the inserted interface card.

### BACKGROUND OF THE INVENTION

The present invention relates to a method of arranging an interface card in a TV/Computer monitor expansion box. According to the present invention, an TV/Computer monitor expansion box is installed into a TV/Computer monitor to hold an interface card, permitting the inserted interface card to be compatible with the invented microprocessor (not PC's CPU) of the TV/Computer monitor and is able to communicate with it. In this way, the microprocessor could runs subjectively to the functions of the inserted interface card. For example, when a tuner card is inserted, the microprocessor enables TV signal to be shown through the TV/Computer monitor in priority. In general, the goal of this invention is to combine and enhance the functions of both TV and Computer monitor. Please note that the TV/Computer monitor, the TV/Computer monitor expansion box, and the microprocessor are all subjects of invention.

A variety of TV and computer monitors are significantly essential nowadays for data display. In order to attract consumers, regular TV and computer monitors are made to provide different functions such as digitalization, high-resolution, multiple sound channels, wide screen, etc. When a TV or computer monitor is made, its functions are unchangeable. Combining variety of functions into a TV or computer monitor would cause the size of the TV/computer monitor to become excessively burdensome, and its high manufacturing cost is unable to attract consumers. In order to provide a TV or computer monitor with an added function, an external peripheral apparatus must be installed. For example, an user could connect the audio output of the TV to a speaker system to enjoy an improved quality of sound by connecting extra tuner or decoder to the TV to improve its receiving and demodulating capacity. However, it is inconvenient to install variety of peripheral apparatus to a TV set to provide it with extra functions. Furthermore, mounting additional peripheral apparatus on a TV set is expensive, and occupies much installation space. Our goal is to invent an interface card and an expansion box that enhance the TV/Computer monitor display without occupying much space and cost.

### SUMMARY OF THE INVENTION

By combining years of experience of the inventors, the present invention has been accomplished under the circumstances of display. One objective of the present invention to provide a method of assembling an interface card in a TV/Computer monitor expansion box that enables the user to detachably install a variety of other interface cards in a TV/Computer monitor to improve its function. It is another objective of the present invention to provide an expansion box that is adapted to receive the interface card, permitting the inserted interface card to be electrically linked to the microprocessor of a TV/Computer monitor. It is still another objective of the present invention to provide an interface card that is compatible to the software (or hardware) of a microprocessor in a TV/Computer monitor and is adapted to control the operation of the microprocessor of the TV/Computer monitor. When an expansion box created according to the objectives of the present invention is mounted inside a TV/Computer monitor, an interface card can be inserted into the expansion box to become electrically connected to the microprocessor of the TV/Computer monitor so that the microprocessor of the TV/Computer monitor is controlled to drive the TV/Computer monitor to run according to the functions of the inserted interface card. The design of the expansion box enables the user to detachably install the desired interface card by himself or herself without receiving special training. To achieve the aforementioned objectives, there is a provided method of arranging an interface card in a TV/Computer monitor expansion box which includes the step of installing a TV/Computer monitor expansion box in a TV/Computer, monitor and the step of inserting an interface card into the TV/Computer monitor expansion box. This permits the inserted interface card to be electrically connected to the microprocessor of the TV/Computer monitor so that the microprocessor of the TV/Computer monitor is controlled to operate functions of the inserted interface card.

The present invention already has a patent in Taiwan and a pending patent in China. However, it is our best interest to bring our product to the United States as well.

### BRIEF DESCRIPTION OF THE DRAWINGS

FIG. 1 is an elevated view of a TV/Computer monitor expansion box according to the present invention.

FIG. 2 is an intensified view of the TV/Computer monitor expansion box shown in FIG. 1.

FIG. 3 is a side view of the TV/Computer monitor expansion box shown in FIG. 1.

FIG. 4 is a sectional view taken along line IV-IV of FIG. 1.

FIG. 5 is another sectional view of the present invention, showing the retainer member of the cover of the TV/Computer monitor expansion box fastened to the inside wall of the monitor.

FIG. 6 is an applied view of the present invention, showing the TV/Computer monitor expansion box installed in a TV/Computer monitor.

FIG. 7 is a circuit block diagram of an interface card according to the present invention.

### DETAILED DESCRIPTION OF THE PREFERRED EMBODIMENT

The present invention is to install an expansion box in a TV/Computer monitor to receive an interface card, permitting the software (or hardware) of the interface card to be compatible to or to communicate with the microprocessor of the TV/Computer monitor, so that when the microprocessor is started, it runs subjectively to the function of the inserted interface card. For example, when a tuner interface card is inserted, the microprocessor enables video signal to be shown in priority. If an interface card that comprises TV TUNER, CLOSED, CAPTION, TELETEXT, and BI-LANGUAGE tuner box is inserted into the expansion box, a video signal is sent to the microprocessor of the TV/Computer monitor, causing it to show processed video signal through the screen by means 31.5 KHZ horizontal frequency. This method eliminates the drawback of conventional crossed scanning method, which causes the picture to jump or flash.

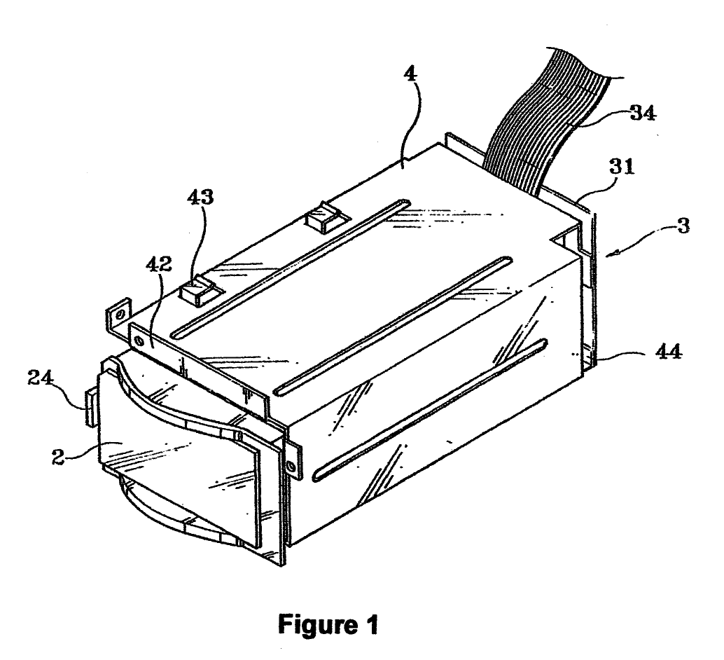

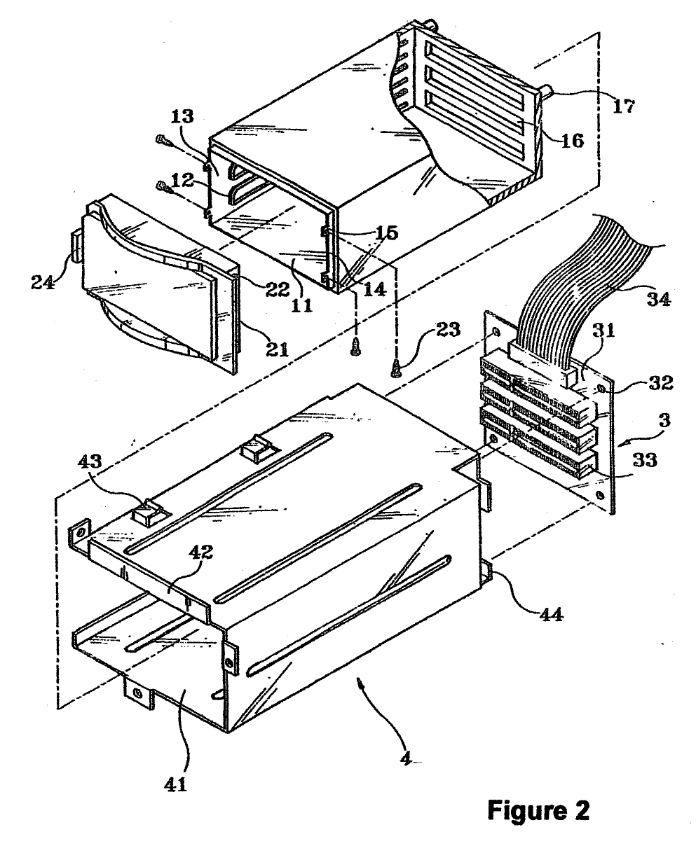

Referring to FIGS. 1 and 2, the TV/Computer monitor expansion box is shown comprised of a case 1, a cover 2, an electrical connector 3, and an outer shell 4.

Case 1 consists of the followings: a receiving chamber 11 adapted to receive an interface card (not shown in picture); symmetrical rails 12 longitudinally coupled inside the receiving chamber 11 and defining abundant sliding tracks 13 into which the interface cards are inserted; a forwardly extended coupling flange 14 around the front open side of the receiving chamber 11, a pair of tabs 15 forwardly extended from the coupling flange 14 on two opposite sides; numerous insertion slots 16 at the rear close side of the receiving chamber 11 that could be connected to circuit board 31 on top of electrical connector 3; and two mounting rods 17 bilaterally raised from the rear close side of the receiving chamber 11 on the outside and adapted for fastening to the outer shell 4.

The cover 2 consists of the followings: a backwardly extended coupling flange 21 adapted for coupling to the forwardly extended coupling flange 14 of case 1; a pair of screw holes 22 symmetrically inclined on the backwardly extended coupling flange 21 and adapted for connecting to the tabs 15 by screws 23; and a retainer member 24 forwardly extended from its one side and adapted for securing to an inside wall of the monitor.

The electrical connector 3 consists of the followings: a circuit board 31; a plurality of ports 33 on the circuit board 31; and a bus line 34 adapted to connect the circuit board 31 to the electrical circuit of the monitor. The circuit board 31 has variety of screws adapted for connecting to the screw hole 32 on the rear end of outer shell 4.

The outer shell 4 fits over the case 1. It consists of the followings: a receiving chamber 41 adapted to receive the casing 1; a plurality of monitor mounting flanges 42 and retainer strips 43 adapted for fastening to the inside of the monitor; and numerous connector mounting flanges 44 at its back side adapted for holding the electrical connector 3.

By means of the monitor mounting flanges 42 and the retainer strips 43, the outer shell 4 is fixed to the inside of the monitor. After the outer shell 4 has been installed in the monitor, the electrical connector 3 is securely fastened to the connector mounting flanges 44 of the outer shell 4, and then case 2 is inserted into the receiving chamber 41 of the outer shell 41, permitting the ports 33 of the electrical connector 3 to be respectively inserted into the insertion slots 16 of case 1.

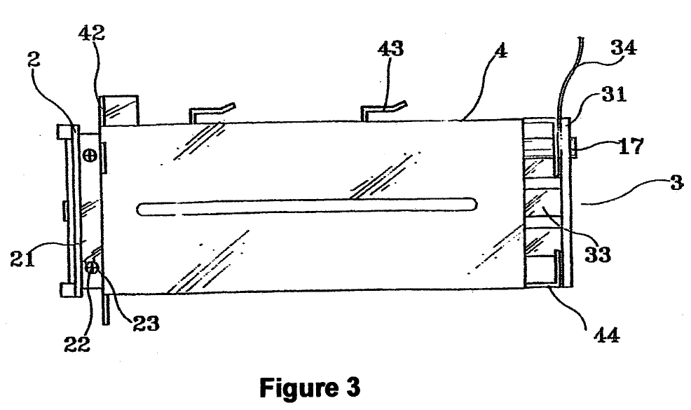

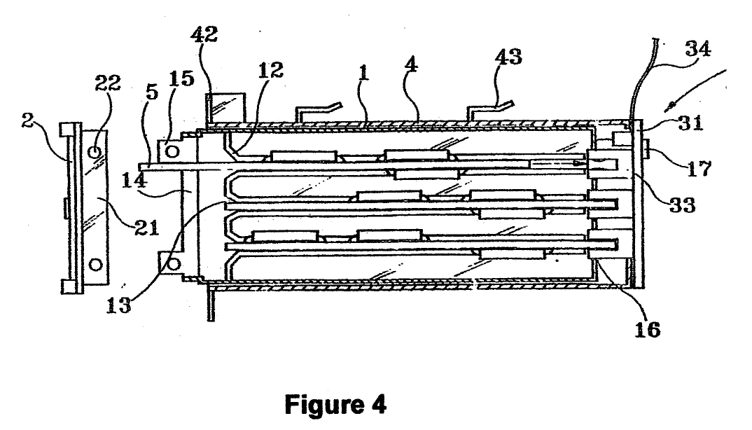

Referring to FIGS. 3 and 4, when the cover 2 is disconnected from the casing 1, an interface card 5 could then be inserted into one of the sliding tracks 13 inside case 1, permitting the gold fingers 0.51 (not shown) of the inserted interface card 5 to be plugged into one of the ports 33 of the electrical connector 3. After the installation of the interface card 5, the cover 2 is closed on case 1 again.

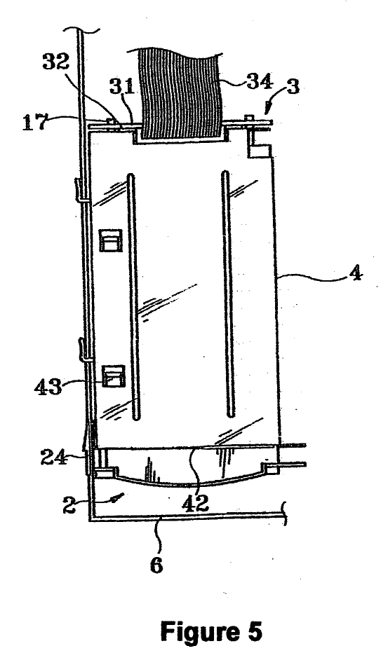

Referring to FIG. 5, when the cover 2 is covered on case 1 before threading screws 23 into the screw holes 22, the retainer member 24 is fastened to the inside wall of the monitor 6 to secure cover 2 into place.

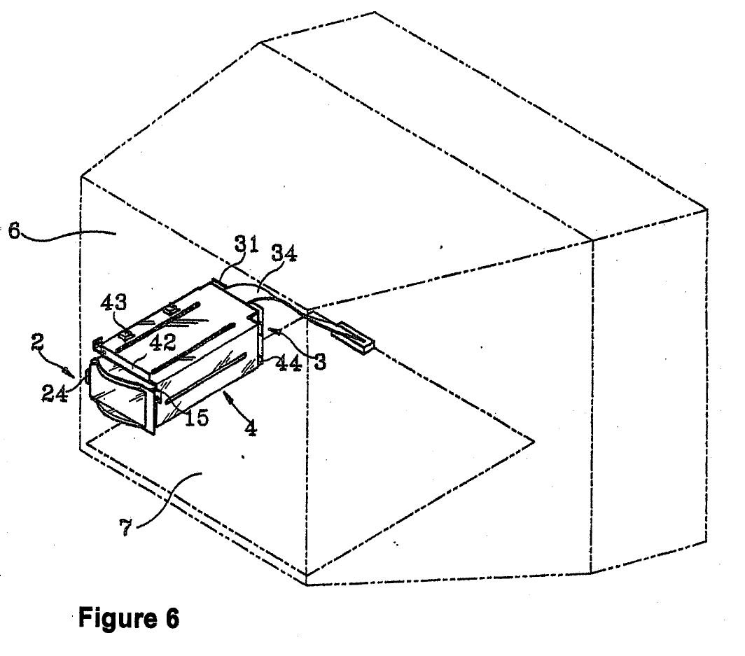

Referring to FIG. 6, when the expansion box is installed into monitor 6, the bus line 34 of the expansion box is connected to the motherboard 7 of the monitor 6, therefore the inserted interface card 5 is electrically connected to the motherboard 7 of the monitor 6 to provide it with additional function.

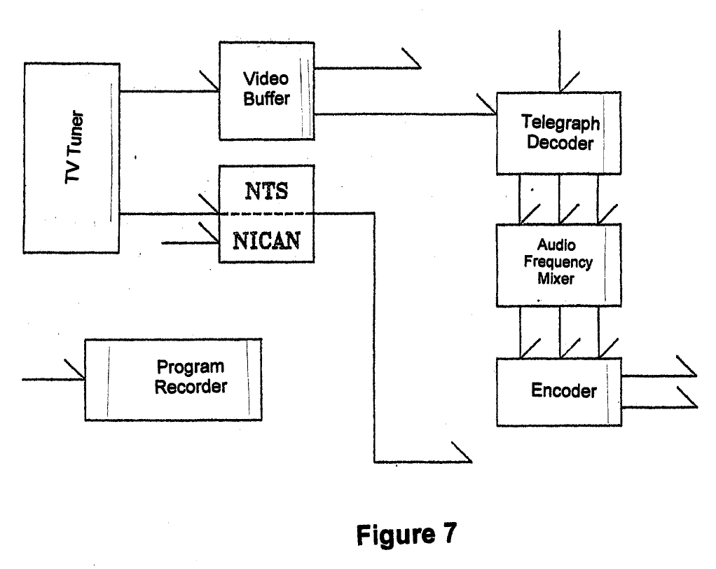

An interface card could be made subjectively to the circuit diagram shown in FIG. 7. Alternatively, any particular circuit diagram with a particular function may be employed for making an interface card for mounting in the expansion box according to the present invention.

The present invention achieves a variety of functions as outlined hereinafter:

A. When no interface card is inserted into the TV/Computer monitor expansion box and the TV/Computer monitor is started, the software program in the microprocessor of the, TV/Computer monitor works independently, and computer signal is shown in priority. If a TV interface card is installed in the TV/Computer monitor expansion box and the TV/Computer monitor is started, the software program of the TV interface card is compatible with the microprocessor of the TV/Computer monitor, and TV signal is shown in priority.

B. When a video compressor/decompressor/fax modem interface card is installed in the TV/Computer monitor expansion box, video signal of picture taken from a video conference is compressed by the video compressor of the video compressor/decompressor/fax modem interface card and then transmitted to an opponent's monitor through the fax modem of the video compressor/decompressor/fax modem interface card. In the same manner, compressed video signal received from is the opponent through the fax modem of the video compressor/decompressor/fax modem interface card is decompressed by the decompressor of the video compressor/decompressor/fax modem interface card, and then shown through the TV/Computer monitor.

C. When a multi-function video processing interface card is installed, video signal is processed as desired (for example, PIP, mask, picture pause, etc.)

As indicated above, when an interface card is installed in the TV/Computer monitor expansion box, the TV/Computer monitor is controlled to run subjectively to the function of the inserted interface card. The expansion box could be made in the form of a bus or expansion port to serve as communication means between an interface card and a microprocessor (not CPU) of a motherboard of a TV/Computer monitor, making the installed interface card to be rapidly and efficiently compatible to the microprocessor. Furthermore, the design of the TV/Computer monitor expansion box enables the user to quickly install an interface card into position, or to easily remove an inserted interface card from the expansion box.

It is important to understand that the drawings are designed for the purpose of illustration only; they are not intended as a definition of the limits and scope of the invention disclosed.

What the invention claimed is:

1. A method of arranging an interface card in a TV/Computer monitor expansion box, comprising the steps of:
i) installing a mentioned TV/Computer monitor expansion box in a TV/Computer monitor;
ii) inserting an interface card into the mentioned TV/Computer monitor expansion box, permitting the inserted interface card to be electrically connected to a mentioned microprocessor of the mentioned TV/Computer monitor;
iii) enabling the inserted interface card to be compatible to or to communicate with the mentioned microprocessor of the mentioned TV/Computer monitor, permitting the mentioned microprocessor of the mentioned TV/Computer monitor to function subjectively to the software or hardware of the inserted interface card; and
iv) enabling TV/Computer monitor expansion box to let the inserted interface card be electrically connected to the mentioned microprocessor of the mentioned TV/Computer monitor, permitting the software of the inserted interface card to be compatible to microprocessor of the TV/Computer monitor, and let the microprocessor of the TV/Computer monitor control the TV/Computer monitor to run subjectively to the software of the inserted interface card.

2. The method of claim 2, wherein said TV/Computer expansion box is made in the form of a bus or expansion port.

3. The method of claim 1, wherein the inserted interface card could be a tuner box, V8 camera interface card, or any interface card of a particular function.
